(19) United States
(12) Patent Application Publication
(10) Pub. No.: US 2007/0131386 A1
(43) Pub. Date: Jun. 14, 2007

(54) FIN UNIT FOR A COOLER

(76) Inventor: Ming-Kun Tsai, Lin Nei Hsiang (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/302,251

(22) Filed: Dec. 14, 2005

(51) Int. Cl. H05K 7/20

(52) U.S. Cl. 165/80.3; 165/185; 361/704; 257/722

(57) ABSTRACT

A fin unit for a cooler includes a heat-conducting member, a plurality of helical elongate twisted fins and a fan. The heat-conducting member or a heat generator has its surface fixed with the plurality of helical elongated twisted fins. When the fan is started to operate, air convection is produced among the helical elongated members, forming helical whirls to increase contact and collision of the air with the helical elongated twisted fins, enhancing effect of heat dissipation.

### BACKGROUND OF THE INVENTION

1. Field of the Invention

This invention relates to a fin unit for a cooler, particularly to one having the surface of a heat-conducting member or the surface of a heat generator fixed with a plurality of helical elongated twisted fins, having excellent effect of heat dissipation.

2. Description of the Prior Art

Generally, a CPU is the most important element of a computer. When a computer system is started to operate, the CPU will read the commands and the data of various kinds of software from a memory. After logic and mathematical operation, the UPU will store the result in the memory, and will attain the object of data processing through communication of the mother-board and the peripheral devices, Therefore, any work in the interior of the mainframe of a computer cannot be accomplished unless it is processed by the CPU, and the faster the processing speed of the CPU is, the more efficient the computer becomes. But one thing that cannot be neglected is the increase of heat energy, and the fact is that the faster the processing speed of the CPU is, the higher the temperature of the CPU becomes. If the temperature of the CPU rises continuously, it will affect the processing speed and lower the work efficiency of the CPU and make the computer hang or down and even cause the CPU to be burned down. For dissipating and lowering the high temperature produced by the CPU, the CPU is provided thereon with a cooler.

A conventional cooler 91 for the CPU of a computer is horizontally positioned on the CPU 92, as shown in FIG. 1. The cooler 91 is provided with lots of fins 912 spaced apart equidistantly on a flat plate 911 and has a fan 93 positioned above. Thus, the high temperature produced by the CPU 92 will be conducted to the fins 912 of the cooler 91 through the flat plate 911 and the fan 93 is started to actuate the surrounding air to produce air convection for dissipating hot air and lowering the temperature so as to prevent the CPU 92 from breaking down due to excessively high temperature and keep the CPU 92 operating normally.

However, since the fins of a conventional cooler are thin plates positioned side by side equidistantly; therefore, when the fan is started to actuate the surrounding air to produce air convection, the air can only be sucked to flow upward from under so only a little of the air may collide and contact with the fins, thus having little effect in heat dissipation. Therefore, many computer users are not satisfied with the heat dissipating effect of the conventional cooler because it is likely to render the computer hang or down and cause loss of data when the temperature of the CPU rises excessively high and heat dissipation of the CPU is imperfect.

### SUMMARY OF THE INVENTION

The objective of the invention is to offer a fin device for a cooler, including a heat-conducting unit, a plurality of helical elongated twisted fins and a fan. The heat-conducting member or the heat generator has its surface fixed with the plurality of helical elongated twisted fins, and the fan is assembled above the helical elongated twisted fins. The fan is started to operate and actuate the surrounding air to produce air convection among the helical elongated twisted fins to form helical whirls to increase contact and collision of the air with the helical elongated twisted fins, thus achieving excellent effect of heat dissipation.

### BRIEF DESCRIPTION OF DRAWINGS

This invention will be better understood by referring to the accompanying drawings, wherein:

FIG. 1 is a front view of the fin unit of a conventional cooler;

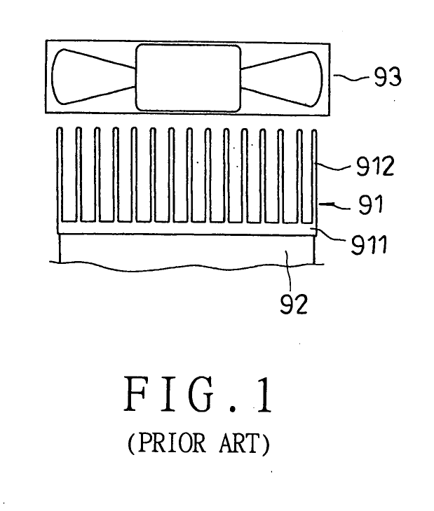

FIG. 2 is a perspective view of a first preferred embodiment of a fin unit for a cooler in the present invention;

FIG. 3 is a cross-sectional view of the first preferred embodiment of the fin unit for a cooler in the present invention;

FIG. 4 is a cross-sectional view of a second preferred embodiment of a fin unit for a cooler in the present invention; and

FIG. 5 is another cross-sectional view of the second preferred embodiment of the fin unit for a cooler in the present invention.

### DETAILED DESCRIPTION OF THE PREFERRED EMBODIMENT

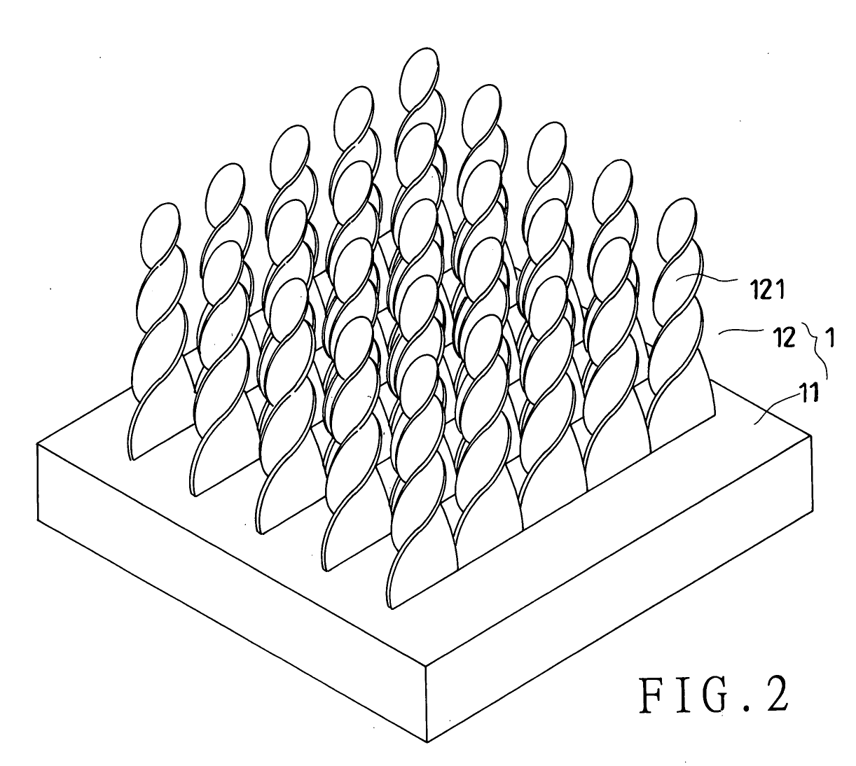

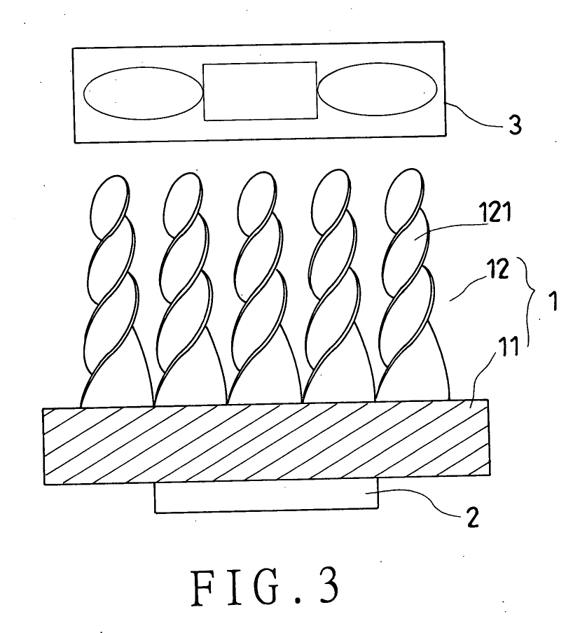

A first preferred embodiment of a fin unit for a cooler 1 in the present invention, as shown in FIGS. 2 and 3, is assembled on a heat generator 2. The fin unit is composed of a heat-conducting member 11, fins 12 and a fan 3. The heat-conducting member 11 is a flat plate horizontally positioned on the heat generator 2 and the fan 3 is assembled above the fins 12.

The fins 12 are cut, drawn and twisted to form helical elongated twisted fins 121. Thus, when the fan 3 is started to operate, the surrounding air will be actuated to produce air convection among the helical elongated twisted fins 121 to form helical whirls to increase contact and collision of the air with the helical elongated twisted fins 121 for elevating effect of heat dissipation.

In using, firstly, the flat-plate heat-conducting member 11 of the fin unit 1 is horizontally positioned on the heat generator 2 and the fan 3 is assembled above the helical elongated twisted fins 121. Then, the fan 3 is started to operate and actuate air to produce air convection among the helical elongated twisted fins 121. Since the fins 12 are formed into the helical elongated twisted fins 121 fixed upright on the heat-conducting unit 11; therefore, the air will bump against the helical elongated twisted fins 121 and produce helical whirls, thus increasing contact and collision of the air with the helical elongated twisted fins 121 for enhancing effect of heat dissipation.

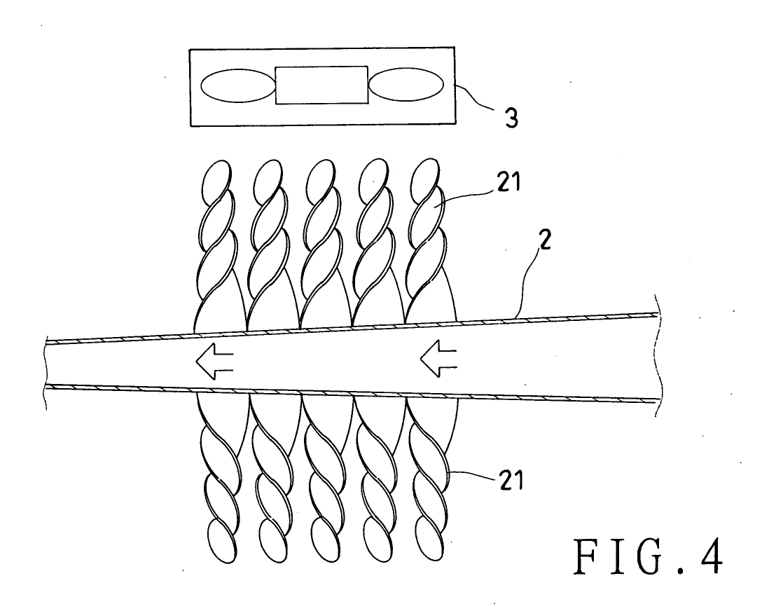

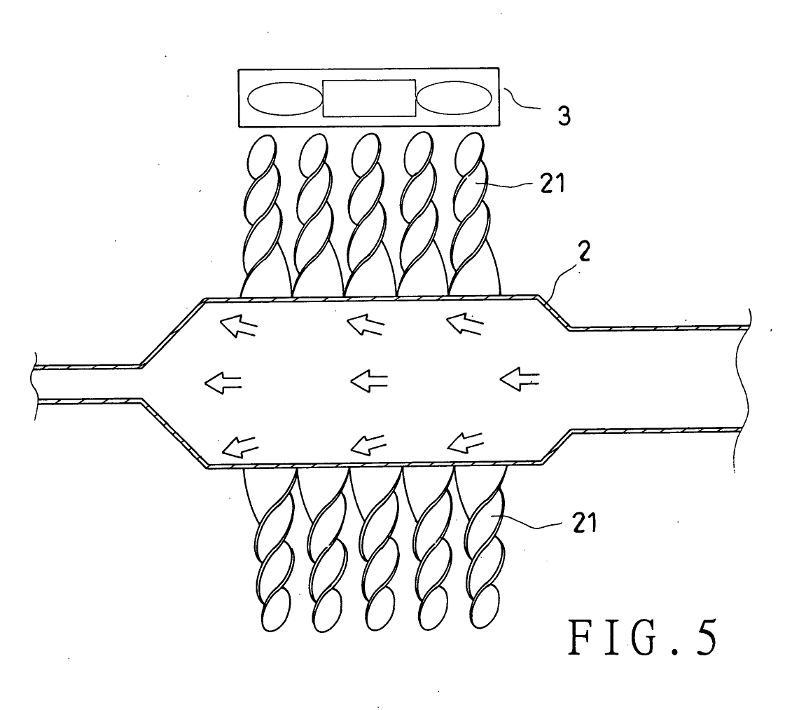

A second preferred embodiment of a fin device for a cooler in the present invention, as shown in FIGS. 4 and 5, includes a plurality of helical elongated twisted fins 21 fixed on the surface of a heat generator 2 and a fan 3 assembled above one side of the helical elongated twisted fins 2. When the fan 3 is started to operate and produce air convection among the helical elongated twisted fins 21 to form helical whirls, able to increase contact and collision of the air with the helical elongated twisted fins 21, enhancing effect of heat dissipation. As can be understood from the above description, this invention has the following advantages.

1. The heat-conducting member or the heat generator has its surface fixed with a plurality of helical elongated twisted fins. When the fan is started to operate, there will produce air convection among the helical elongated twisted fins to form helical whirls so as to increase contact and collision of the air with the helical elongated twisted fins, elevating effect of heat dissipation.

2. The helical elongated twisted fins are respectively tapered to the upper end; therefore, the heat energy produced by the heat generator can quickly be conducted to the upper ends of the helical elongated twisted fins, thus enhancing effect of heat dissipation.

While the preferred embodiments of the invention have been described above, it will be recognized and understood that various modifications may be made therein and the appended claims are intended to cover all such modifications that may fall within the spirit and scope of the invention.

What is claimed is:

1. A fin unit for a cooler comprising a heat-conducting member, a plurality of fins and a fan, said heat-conducting unit mounted on a heat generator, said fins formed as helical elongated twisted fins fixed on said heat-conducting member, said fan positioned above said helical elongated twisted fins, said fan started to operate to produce air convection among said helical elongated twisted fins to form helical whirls.

2. The fin unit for a cooler as claimed in claim 1, wherein the heat generator has its surface cut, drawn and twisted to form said helical elongated twisted fins.
